(19) United States
(12) Patent Application Publication
(10) Pub. No.: US 2009/0230890 A1
(43) Pub. Date: Sep. 17, 2009

(54) ORGANIC ELECTROLUMINESCENT DISPLAY DEVICE AND METHOD OF PRODUCING THE SAME

(75) Inventor: Kazuhiro Takahara, Kanagawa (JP)

Correspondence Address: SUGHRUE-265550, 2100 PENNSYLVANIA AVE. NW, WASHINGTON, DC, 20037-3213, US

(73) Assignee: FUJIFILM Corporation, Tokyo (JP)

(21) Appl. No.: 12/404,523

(22) Filed: Mar. 16, 2009

(30) Foreign Application Priority Data
Mar. 17, 2008 (JP) 2008-068084

(51) Int. Cl. H05B 41/36; H01J 9/00

(52) U.S. Cl. 315/307; 445/24

(57) ABSTRACT

An organic electroluminescent display device in which a plurality of light-emitting cells each having an organic electroluminescent portion are arranged on a substrate, wherein a plurality of organic electroluminescent portions included in the plurality of light-emitting cells include at least three organic electroluminescent portions which emit different colors, each of the light-emitting cells has a driving transistor which drives the organic electroluminescent portion included in the light-emitting cell, and an amount of an output current of the driving transistor under same driving conditions is different depending on emission color of the organic electroluminescent portion included in the light-emitting cell including the driving transistor.

### CROSS-REFERENCE TO RELATED APPLICATIONS

This application claims the benefit of Japanese Patent Application JP 2008-068084, filed Mar. 17, 2008, the entire content of which is hereby incorporated by reference, the same as if set forth at length.

### FIELD OF THE INVENTION

The present invention relates to an organic electroluminescent display device in which a plurality of light-emitting cells each having an organic electroluminescent portion are arranged on a substrate.

### BACKGROUND OF THE INVENTION

Usually, an organic electroluminescent (organic EL) display device which can be used in various display apparatuses is produced by using a process similar to a semiconductor production process, and forming light-emitting cells each having an organic electroluminescent portion on a substrate such as a semiconductor. The light-emitting cells are used for displaying pixels constituting an image or the like to be displayed, respectively.

The organic EL uses a phenomenon called injection electroluminescence in which light is emitted by recombination of an electron-hole pair. Since the luminescence principle is similar to that of an LED (Light-Emitting Diode), an organic EL portion is also called an OLED (Organic Light-Emitting Diode).

In order to surely control lighting/extinction of each of many light-emitting cells which are arranged two-dimensionally, usually, an active matrix drive system in which an independent active drive element such as a TFT (Thin Film Transistor) is disposed for each of the cells is used.

In the case of an organic electroluminescent display device, a circuit which is configured as shown in, for example, FIG. 8 of JP-A-2005-300786 (corresponding to US2005/0225253A1) is formed for each cell. Namely, a driving transistor (80) which is connected in series to an organic EL element (70) is disposed in order to control energization of the element, and a capacitor for holding a signal and a selection transistor (10) for switching the signal are connected to the input of the driving transistor.

At a timing when a signal which is to be displayed in the cell appears, the selection transistor is temporarily turned on, and the necessary signal is held by the capacitor. Therefore, the driving transistor for the cell supplies a current corresponding to the input signal to the organic EL element, so that the luminous intensity of the organic EL element is controlled by the current.

In an organic EL display device in which many light-emitting cells are arranged, it is important to increase the aperture ratio of each cell. More specifically, each cell tends to have a small area, and therefore a sufficient luminous intensity cannot be obtained and a clear display is not enabled unless the area ratio of the luminous region to the cell is increased as far as possible. Actually, when transistors or the like of a circuit for driving cells are increased in size, light is blocked by the transistors or the like, so that the aperture ratio of each cell is lowered and the luminous intensity is reduced.

In the prior art disclosed in JP-A-2005-300786 (corresponding to US2005/0225253A1), in order to enable the channel of the driving transistor to be shortened, therefore, the carrier mobility of the driving transistor is made lower than that of the selection transistor. Specifically, a silicon-based semiconductor is used as the active layers (regions where the channel is formed) of the transistors, and their carrier mobilities can be changed depending on the difference of their grain sizes.

JP-A-2006-186319 (corresponding to US2006/0113549A1) discloses a luminescence device which is configured by using an amorphous oxide semiconductor in the active layer of a transistor.

### SUMMARY OF THE INVENTION

In the case where transistors (TFTs) are configured by using polysilicon as disclosed in JP-A-2005-300786 (corresponding to US2005/0225253A1), however, the mobility is as large as about 100 to 200, and hence the channel length (L) of a driving transistor must be increased so that the current amount is restricted. When the channel length is large, the ratio of the region of the transistor to the area of a cell is large, and hence the aperture ratio is lowered. In the case where an organic electroluminescent display device for realizing a high-definition display apparatus is to be formed, therefore, a transistor cannot be sometimes placed for each cell.

By contrast, in order to perform a color display, at least three kinds of organic EL elements which respectively emit the colors of R (red), G (green), and B (blue) must be disposed. In the present circumstances, however, the light emission efficiencies of organic EL elements of R, G, and B are different from one another. In order to ensure an adequate white balance, therefore, peak currents respectively flowing through organic EL elements of R, G, and B must be changed depending on the color. As a method of changing the peak currents depending on the color, for example, the channel lengths L of the driving transistors may be adjusted, or the power source voltage may be adjusted. When the channel lengths L of the driving transistors are increased, however, there is a problem in that the aperture ratio is reduced. In order to adjust the power source voltage depending on the color, moreover, the circuit configuration is inevitably complicated.

It is an object of the invention to provide an organic electroluminescent display device in which the aperture ratio of each of light-emitting cells can be prevented from being reduced, and, when a color display is to be performed, an adequate white balance is easily ensured, and a method of producing the device.

The organic electroluminescent display device of the invention is an organic electroluminescent display device in which a plurality of light-emitting cells each having an organic electroluminescent portion are arranged on a substrate, wherein a plurality of organic electroluminescent portions included in the plurality of light-emitting cells include at least three kinds of organic electroluminescent portions which emit different colors, each of the light-emitting cells has a driving transistor which drives the organic electroluminescent portion included in the light-emitting cell, and an amount of an output current of the driving transistor under same driving conditions is different depending on the emission color of the organic electroluminescent portion included in the light-emitting cell including the driving transistor.

In the organic electroluminescent display device of the invention, a difference in amount of the output currents of the driving transistors is obtained from a difference in mobility of the driving transistors.

In the organic electroluminescent display device of the invention, the plurality of organic electroluminescent portions included in the plurality of light-emitting cells include R-color organic electroluminescent portions which emit red light, G-color organic electroluminescent portions which emit green light, and B-color organic electroluminescent portions which emit blue light, and, in the driving transistors, an R-color mobility indicating mobilities of R-color driving transistors which drive the R-color organic electroluminescent portions, a G-color mobility indicating mobilities of G-color driving transistors which drive the G-color organic electroluminescent portions, and B-color mobility indicating mobilities of B-color driving transistors which drive the B-color organic electroluminescent portions have a relationship of (R-color mobility)>(G-color mobility)>(B-color mobility).

In the organic electroluminescent display device of the invention, a difference in mobility of the driving transistors is obtained from a difference in electron carrier concentration of active layers of the driving transistors.

In the organic electroluminescent display device of the invention, a difference in amount of the output currents of the driving transistors is obtained from a difference in thickness of gate insulating films of the driving transistors.

In the organic electroluminescent display device of the invention, the plurality of organic electroluminescent portions included in the plurality of light-emitting cells include R-color organic electroluminescent portions which emit red light, G-color organic electroluminescent portions which emit green light, and B-color organic electroluminescent portions which emit blue light, and, in the driving transistors, an R-color gate insulating film thickness indicating thicknesses of gate insulating films of R-color driving transistors which drive the R-color organic electroluminescent portions, a G-color gate insulating film thickness indicating thicknesses of gate insulating films of G-color driving transistors which drive the G-color organic electroluminescent portions, and a B-color gate insulating film thickness indicating thicknesses of gate insulating films of B-color driving transistors which drive the B-color organic electroluminescent portions have a relationship of (R-color gate insulating film thickness)<(G-color gate insulating film thickness)<(B-color gate insulating film thickness).

In the organic electroluminescent display device of the invention, a difference in amount of the output currents of the driving transistors is obtained from a difference in dielectric constant of gate insulating films of the driving transistors.

In the organic electroluminescent display device of the invention, the plurality of organic electroluminescent portions included in the plurality of light-emitting cells include R-color organic electroluminescent portions which emit red light, G-color organic electroluminescent portions which emit green light, and B-color organic electroluminescent portions which emit blue light, and, in the driving transistors, an R-color insulating film dielectric constant indicating dielectric constants of gate insulating films of R-color driving transistors which drive the R-color organic electroluminescent portions, a G-color insulating film dielectric constant indicating dielectric constants of gate insulating films of G-color driving transistors which drive the G-color organic electroluminescent portions, and a B-color insulating film dielectric constant indicating dielectric constants of gate insulating films of B-color driving transistors which drive the B-color organic electroluminescent portions have a relationship of (R-color insulating film dielectric constant)>(G-color insulating film dielectric constant)>(B-color insulating film dielectric constant).

In the organic electroluminescent display device of the invention, active layers of the driving transistors are formed by an amorphous oxide semiconductor.

The method of producing an organic electroluminescent display device of the invention is a method of producing an organic electroluminescent display device in which a plurality of light-emitting cells each having an organic electroluminescent portion are arranged on a substrate, wherein a plurality of organic electroluminescent portions included in the plurality of light-emitting cells include at least three kinds of organic electroluminescent portions which emit different colors, each of the light-emitting cells has a driving transistor which drives the organic electroluminescent portion included in the light-emitting cell, the method includes: a first step of forming active layers of the driving transistors on the substrate; and a second step of irradiating the active layers of the driving transistors which drive at least two kinds of organic electroluminescent portions among the at least three kinds of organic electroluminescent portions, respectively, with ultraviolet rays or plasma, and, in the second step, an amount of irradiation of the ultraviolet rays or plasma on the active layers is different depending on the kinds of the organic electroluminescent portions which are driven by the driving transistors including the active layers.

According to the invention, an organic electroluminescent display device in which the aperture ratio of each of light-emitting cells can be prevented from being reduced, and, when a color display is to be performed, an adequate white balance is easily ensured, and a method of producing the device are realized.

### BRIEF DESCRIPTION OF THE DRAWINGS

FIGS. 1A to 1C are electrical circuit diagrams respectively showing three kinds of circuit configurations of one of many light-emitting cells included in the organic electroluminescent display device of an embodiment.

FIG. 2 is an electrical circuit diagram showing the basic circuit configuration of one of the many light-emitting cells included in the organic electroluminescent display device of the embodiment.

FIG. 3 is a timing chart showing examples of signals which are applied to the circuit shown in FIG. 2.

FIG. 4 is a graph showing current-voltage characteristics of a transistor included in the circuit shown in FIG. 2.

FIGS. 5A to 5C are views showing specific examples of various conditions in the case where the light-emitting cells of the organic electroluminescent display device are actually driven.

FIG. 6 is a longitudinal section view showing specific example 1 of a production process of forming two transistors having different mobility characteristics on one substrate.

FIG. 7 is a longitudinal section view showing specific example 2 of the production process of forming two transistors having different mobility characteristics on one substrate.

FIG. 8 is a flowchart showing example (1) of a process procedure of a production process of forming three kinds of transistors having different mobility characteristics on one substrate.

FIG. 9 is a flowchart showing example (2) of the process procedure of the production process of forming three kinds of transistors having different mobility characteristics on one substrate.

### DETAILED DESCRIPTION OF THE INVENTION

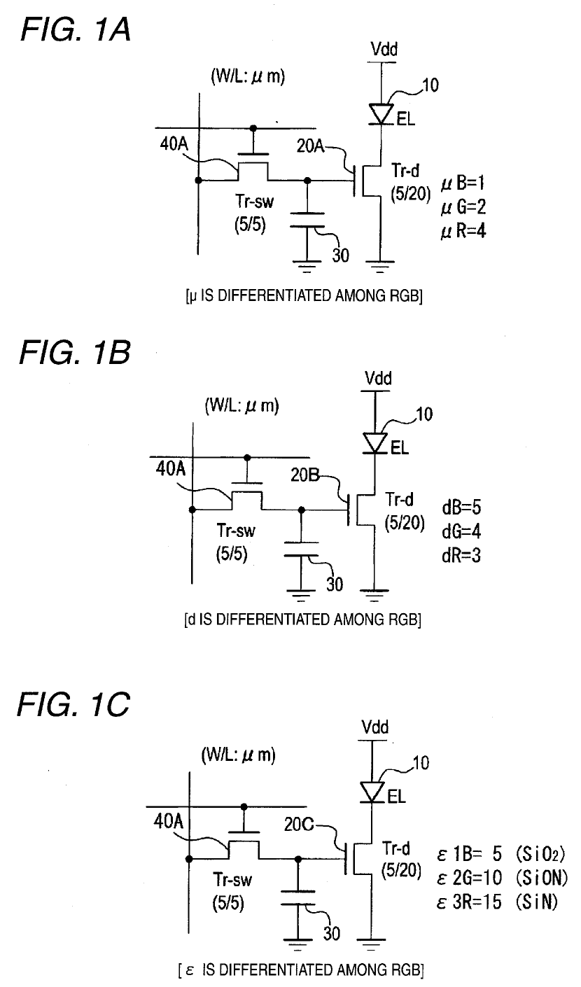

A specific embodiment of the organic electroluminescent display device of the invention and the method of producing it will be described with reference to FIGS. 1 to 9.

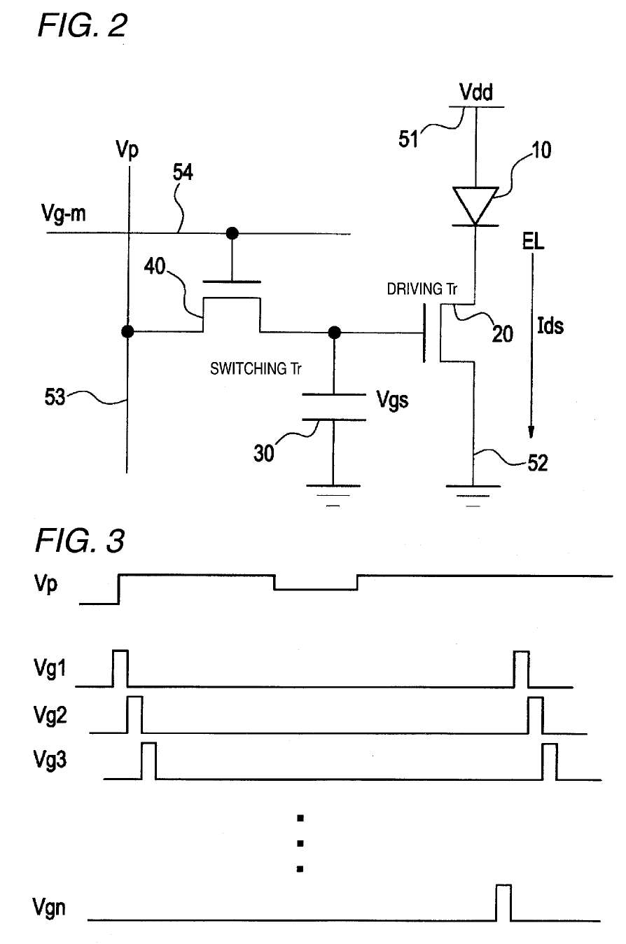

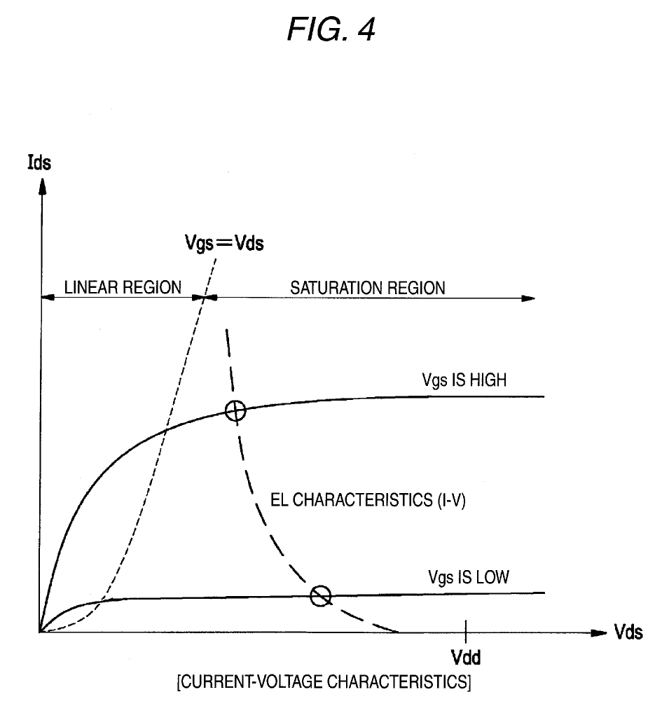

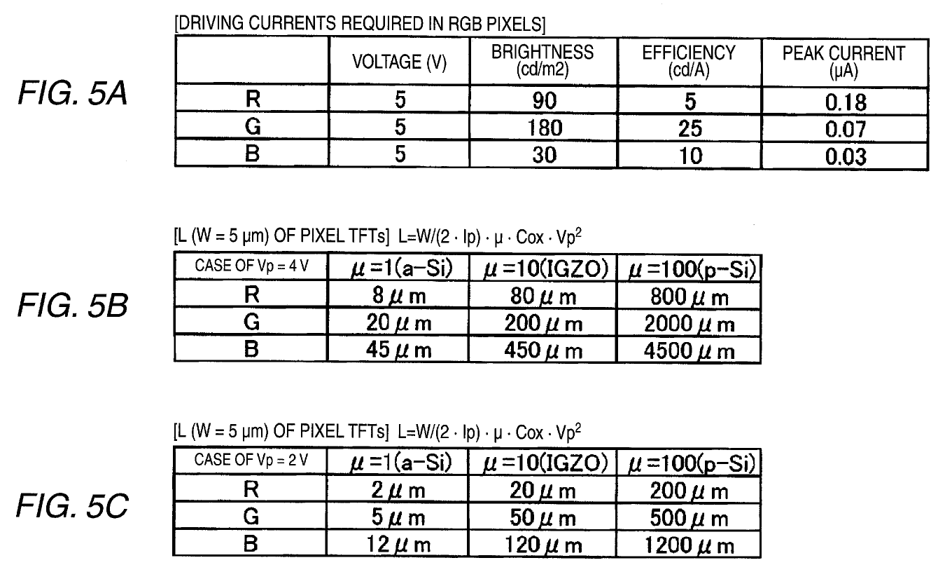

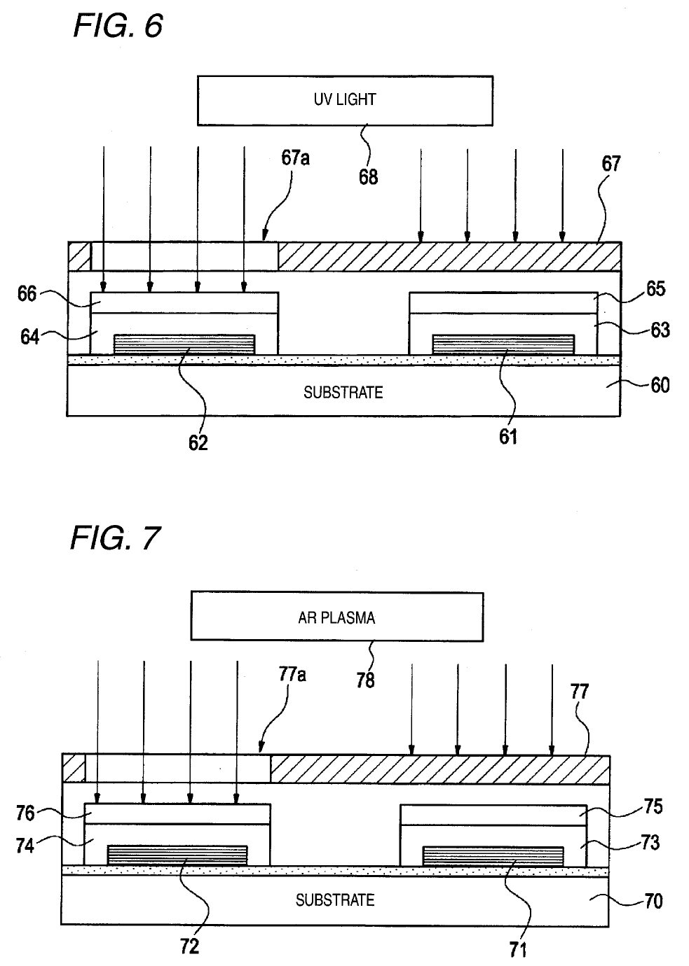

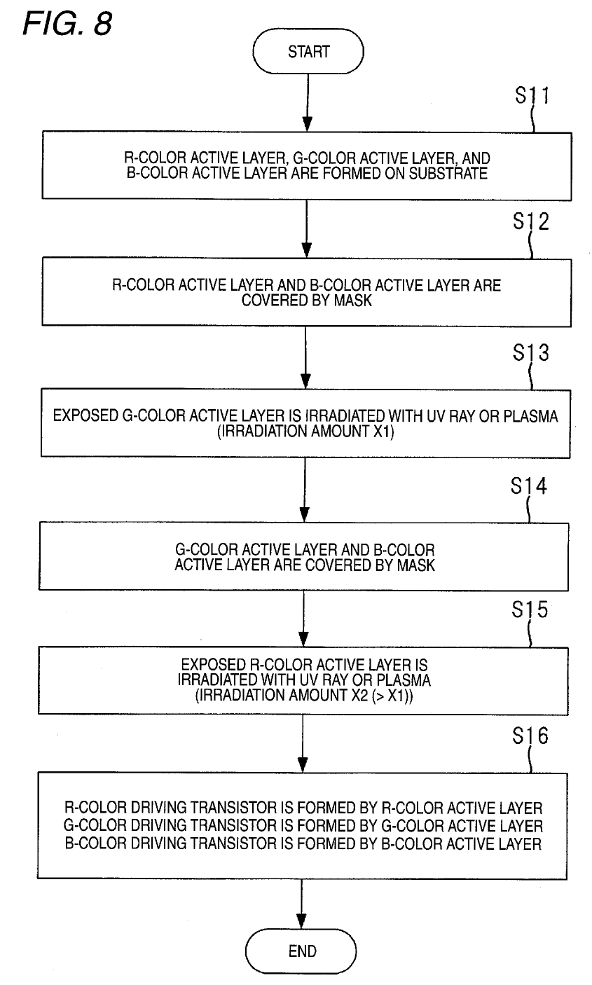

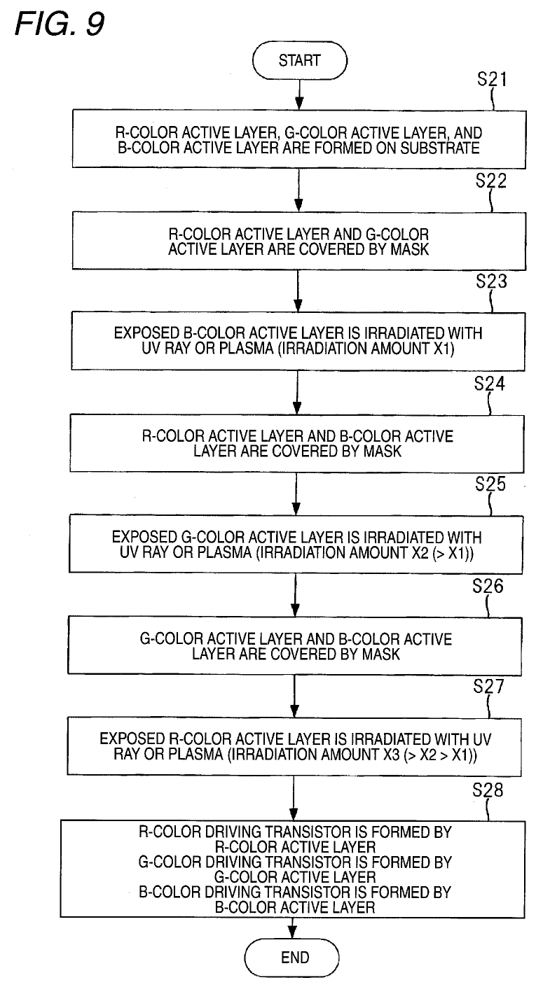

FIGS. 1A to 1C are electrical circuit diagrams respectively showing three kinds of circuit configurations of one of many light-emitting cells included in the organic electroluminescent display device of the embodiment, FIG. 2 is an electrical circuit diagram showing the basic circuit configuration of one of the many light-emitting cells included in the organic electroluminescent display device of the embodiment, FIG. 3 is a timing chart showing examples of signals which are applied to the circuit shown in FIG. 2, FIG. 4 is a graph showing current-voltage characteristics of a transistor included in the circuit shown in FIG. 2, FIGS. 5A to 5C are views showing specific examples of various conditions in the case where the light-emitting cells of the organic electroluminescent display device are actually driven, FIG. 6 is a longitudinal section view showing specific example 1 of a production process of forming two transistors having different mobility characteristics on one substrate, FIG. 7 is a longitudinal section view showing specific example 2 of the production process of forming two transistors having different mobility characteristics on one substrate, FIG. 8 is a flowchart showing example (1) of a process procedure of a production process of forming three kinds of transistors having different mobility characteristics on one substrate, and FIG. 9 is a flowchart showing example (2) of the process procedure of the production process of three kinds of forming transistors having different mobility characteristics on one substrate.

In the embodiment, it is assumed that the invention is applied to an organic electroluminescent display device in which, in the same manner as a display panel of a usual surface display apparatus, many light-emitting cells having the same structure are arranged two-dimensionally at regular intervals in the horizontal and vertical directions. Furthermore, it is assumed that, in order to enable a color display, three kinds of light-emitting cells which respectively emit light of wavelength regions of the colors of R, G, and B are arranged in accordance with predetermined rules. Moreover, it is assumed that, in order to surely control lighting/extinction and the amount of luminescence of each of the many light-emitting cells which are arranged two-dimensionally, an active matrix drive system in which an independent active drive element is disposed for each of the cells is employed. Hereinafter, a light-emitting cell of the kind which emits R light is often referred to as an R-color light-emitting cell, a light-emitting cell of the kind which emits G light is often referred to as a G-color light-emitting cell, and a light-emitting cell of the kind which emits B light is often referred to as a B-color light-emitting cell.

Each of the many light-emitting cells constituting the organic electroluminescent display device has the circuit configuration shown in FIG. 2. Many light-emitting cells having the configuration shown in FIG. 2 are arranged on one substrate by production steps which are similar to those of the semiconductor production process, thereby configuring one organic electroluminescent display device. When an image is to be displayed by the organic electroluminescent display device, usually, each of pixels constituting the image is displayed by luminescence of each of the light-emitting cells. When a color image is to be displayed, three light-emitting cells which respectively emit light of the colors of R (red), G (green), and B (blue) are used for displaying one pixel.

Referring to FIG. 2, each of the light-emitting cells includes an organic EL element (OLED) 10, a driving transistor 20, a capacitor 30, and a switching transistor 40. The organic EL element 10 has an anode and a cathode in the same manner as a light-emitting diode. The anode of the organic EL element 10 is connected to a power source line (to which a DC voltage Vdd is applied) 51, and the cathode is connected to a ground line 52 via the driving transistor 20. Namely, a current Ids flowing through the organic EL element 10 is controlled by the driving transistor 20.

In order to hold the input voltage (Vgs: the gate-source voltage) of the driving transistor 20, the capacitor 30 is connected between the gate electrode of the driving transistor 20 and the ground line.

A program voltage Vp which is used for determining the current Ids flowing through the organic EL element 10 of each of the light-emitting cells is applied to a signal line 53, so that the program voltage Vp is applied through the signal line 53 to the gate electrode of the driving transistor 20 and the capacitor 30 via the switching transistor 40 of each light-emitting cell. Namely, the switching transistor 40 is on-off controlled in order to selectively apply the program voltage Vp to the light-emitting cell. The switching transistor 40 is on-off controlled by a selection signal Vg-m which is applied to a selection control line 54.

In the case where a first light-emitting cell, a second light-emitting cell, a third light-emitting cell, . . . , and an n-th light-emitting cell are sequentially arranged, for example, signals which are temporarily raised to a high level at slightly staggered timings as signals Vg1, Vg2, Vg3, . . . , Vgn shown in FIG. 3 are applied to the cells as the selection signal Vg-m shown in FIG. 2. When the selection signal Vg-m is at the high level, the switching transistor 40 is turned on, and the program voltage Vp is supplied to the gate electrode of the driving transistor 20. At this time, the capacitor 30 is charged or discharged. Therefore, the program voltage Vp is held by the capacitor 30, so that, even after the switching transistor 40 is turned off, the gate voltage (Vgs) of the driving transistor 20 is maintained constant.

FIG. 4 shows characteristics indicating relationships between the output current Ids and the voltage Vds (the drain-source voltage) in the driving transistor 20 shown in FIG. 2. As shown in FIG. 4, when the gate voltage Vgs of the driving transistor 20 is low, the current Ids is reduced, and, when the gate voltage Vgs is high, the current Ids is increased. When the current Ids is small, the amount of luminescence of the organic EL element 10 is reduced, and, when the current Ids is large, the amount of luminescence of the organic EL element 10 is increased.

In the embodiment, it is assumed that the driving transistor 20 is used in the saturation region. In the case where a transistor is used in the saturation region, the current Ids is indicated by the following expression.

Ids=(½)·μ·Cox·(W/L)·(Vgs−Vth)²

Vp=Vgs−Vth

Cox=ε0·εr/d

In the expressions,

μ: the mobility,

W: the channel width of the transistor,

L: the channel length (the distance between the drain and the source) of the transistor,

Vth: the threshold voltage of the transistor,

Vp: the program voltage, εr: the dielectric constant of a material of the gate insulating film, and

d: the thickness of the gate insulating film.

Therefore, parameters which can be used in the adjustment of the current Ids are W/L, μ, d, εr, and Vp.

Next, specific examples of various values in the case where light-emitting cells are actually configured will be described. In this case, the following conditions are assumed to be the characteristics of the organic EL element 10 and the driving transistor 20.

Program voltage (Vp): 4 V/2 V,

Light emitting area (S): 100×100 (μm²)

Peak brightness (Bp): 300 cd/m² (white)

Luminous efficiency (E): R (5)/G (25)/B (10 cd/A)

Peak current (Ip): Ip=Bp/E·S

Thickness of gate insulating film (d): 100 nm

Dielectric constant of gate insulating film (Er): 3.9 (SiO₂)

Mobility (μ): 1 cm2/Vs (in the case where the active layer is made of amorphous silicon (a-Si))
10 cm2/Vs (in the case where the active layer is made of IGZO)
100 cm2/Vs (in the case where the active layer is made of polysilicon (p-Si))

Performance of EL element (light emitting area: 0.1×0.1 mm², white: 300 cd/m²) FIG. 5A shows driving conditions of the organic EL element 10 of one cell which are required for adequately displaying pixels of R, G, and B. The organic EL elements 10 which respectively emit light of R, G, and B are different from one another in luminous efficiency, etc. In order to perform a color display while maintaining an adequate white balance, therefore, the peak currents respectively flowing through the R-color organic EL element 10, the G-color organic EL element 10, and the B-color organic EL element 10 must be controlled so as to be different from one another.

When the power source voltage (Vdd) is changed, for example, the peak currents respectively flowing through the organic EL elements 10 can be changed. In order to control the power source voltage, however, the circuit configuration is inevitably complicated. In the embodiment, a case where a control is performed so that the peak currents respectively flowing through the organic EL elements 10 of R, G, and B are differentiated by a difference in characteristic (the output current amounts Ids) of the driving transistors 20 which control the currents of the organic EL elements 10 is assumed.

As described above, the current Ids can be adjusted by changing the parameter (W/L) of the channel size of the driving transistor 20. As specific examples, FIGS. 5B and 5C show the size of the channel length (L) which is required under conditions that the channel width (W) of the driving transistor 20 is 5 (μm), as conditions of the driving transistors 20 for driving the organic EL elements 10 which respectively emit light of R, G, and B. In the example shown in FIG. 5B, it is assumed that the program voltage (Vp) is 4 V, and, in the example shown in FIG. 5C, it is assumed that the program voltage (Vp) is 2 V.

In the case where the program voltage (Vp) is 4 V as shown in FIG. 5B, when the driving transistors 20 are to be configured by using polysilicon (p-Si), for example, the channel lengths (L) of the driving transistors 20 which are to be placed in light-emitting cells of R, G, and B are 800, 2,000, and 4,500 (μm), respectively. When such transistors having a large channel length are placed in cells, however, the aperture ratio is inevitably reduced, and a large difference is caused in the aperture ratios for R, G, and B. Furthermore, there is a possibility that such transistors having a large channel length cannot be placed in cells.

As shown in FIGS. 5B and 5C, when the program voltage (Vp) is lowered, the channel size (L) can be reduced. In this case, however, the noise level is increased to adversely affect the display quality, and hence the program voltage (Vp) cannot be lowered very much.

Therefore, the characteristics of the driving transistors 20 for R, G, and B are differentiated from one another so that the mobility (μ) of the driving transistor 20 is changed depending on the emission color (R, G, or B) of the organic EL element 10 which is driven by the driving transistor. According to the configuration, even when the channel sizes (L) are not differentiated, the output currents of the driving transistors 20 (the output current amounts of the driving transistors 20 when the transistors are driven under same conditions) can be restricted depending on a difference in mobility (μ). Therefore, the peak currents of the organic EL elements 10 which respectively emit light of R, G, and B can be controlled so that a color display is enabled at an adequate white balance. As a result, in each of the light-emitting cells of R, G, and B, the channel size of the driving transistor can be optimized. When the mobility μ of the driving transistor 20 is reduced, for example, the channel size (L) can be reduced as shown in FIG. 5B, and hence the aperture ratio of the light-emitting cell can be improved.

In a specific example in which the driving transistor 20 is configured by using polysilicon (p-Si) as the active layer, the mobility (μ) can be changed depending on the thickness of the polysilicon layer. When the thickness of the polysilicon layer is small, the mobility (μ) is increased, and, when the thickness is large, the mobility (μ) is decreased.

In the case where the driving transistor 20 is configured by using an amorphous oxide semiconductor (IGZO) as the active layer, the driving transistors 20 having different electron carrier concentrations or mobilities (μ) can be formed by irradiating the active layers with UV rays or argon (Ar) plasma. As the irradiation amount of UV rays or argon (Ar) plasma is more increased, the mobility is further increased. Therefore, the mobility (μ) can be controlled by the irradiation amount of UV rays or plasma. A specific example of a process of irradiating the active layer with UV rays or plasma will be described later.

By contrast, even in the case where the channel size (W/L) and the mobility (μ) are identical, when the thicknesses (d) of the gate insulating films (hereinafter, such a thickness is often referred to as “gate insulating film thickness”) of the driving transistors 20 are adjusted as described above, the output current amounts of the driving transistors 20 can be restricted, and the peak currents of the organic EL elements 10 which respectively emit light of R, G, and B can be controlled so that a color display is enabled at an adequate white balance. Namely, when the gate insulating film thickness (d) is decreased, the peak current is made large, and, when the gate insulating film thickness (d) is increased, the peak current is made small. Therefore, the driving transistors 20 may be formed so that the gate insulating film thicknesses (d) for the light-emitting cells of R, G, and B are different from one another.

Even in the case where the channel size (W/L), the mobility (μ), and the gate insulating film (d) are identical, when materials having different dielectric constants (ε) are used as the materials constituting the gate insulating films of the driving transistors 20 as described above, the output current amounts of the driving transistors 20 can be restricted, and the peak currents of the organic EL elements 10 which respectively emit light of R, G, and B can be controlled so that a color display is enabled at an adequate white balance. Namely, when the driving transistors 20 are configured while the gate insulating films are formed by a material having a large dielectric constant (ε), the peak currents are increased, and, when the driving transistors 20 are configured while the gate insulating films are formed by a material having a small dielectric constant (ε), the peak currents are decreased.

FIGS. 1A to 1C show three configuration examples of a light-emitting cell which is configured by application of the above-described improvement, respectively. In each of FIGS. 1A to 1C, only the configuration of one light-emitting cell is shown. Actually, light-emitting cells of R, G, and B are placed in mutually adjacent positions. The light-emitting cells of R, G, and B are configured in the same manner except that the characteristics of the driving transistors 20 included therein are different from one another.

In the configuration example shown in FIG. 1A, in a similar manner to the case of FIG. 2, the organic EL element 10, a driving transistor 20A, the capacitor 30, and a switching transistor 40A are formed in one light-emitting cell. However, the driving transistors 20A are formed so that their mobilities μ are different depending on the light-emitting cells of R, G, and B.

As shown in FIG. 1A, namely, the driving transistors 20A disposed in the light-emitting cells of R, G, and B are formed so that their mobilities (μR, μG, μB) are “4”, “2”, and “1”, respectively. In other words, the driving transistors 20A included in the light-emitting cells of R, G, and B are formed so that the mobilities have the relationships of (μR>μG>μB).

In the driving transistors 20A shown in FIG. 1A, the channel width W is 5 (μm), and the channel length L is 20 (μm), and, in the switching transistors 40A, the channel width W is 5 (μm), and the channel length L is 5 (μm). Namely, the parameters of the driving transistors 20A relating to the channel size (W/L) are identical in the light-emitting cells of all of R, G, and B. Therefore, a difference is not produced among the aperture ratios of the R-color light-emitting cells, the G-color light-emitting cells, and the B-color light-emitting cells.

A method of forming the driving transistors 20A having different mobilities (μR, μG, μB) on one substrate can be realized by adjusting the thicknesses of the polysilicon layers constituting the driving transistors 20A as described above. In the case where an IGZO layer is used an active layer, in place of the thickness adjustment, the IGZO layer is irradiated with UV rays or Ar plasma, whereby different mobilities (μR, μG, μB) can be formed depending on the difference in irradiation amount.

By contrast, in the configuration example shown in FIG. 1B, in a similar manner to the case of FIG. 2, the organic EL element 10, a driving transistor 20B, the capacitor 30, and the switching transistor 40A are formed in one light-emitting cell. However, the driving transistors 20B are formed so that the thicknesses (d) of their gate insulating films are different depending on the light-emitting cells of R, G, and B.

As shown in FIG. 1B, namely, the driving transistors 20B disposed in the light-emitting cells of R, G, and B are formed so that the thicknesses (dR, dG, dB) of their gate insulating films are “3”, “4”, and “5”, respectively. In other words, the driving transistors 20B included in the light-emitting cells of R, G, and B are formed so that the gate insulating film thicknesses have the relationships of (dR<dG<dB).

In the driving transistors 20B shown in FIG. 1B, the channel width W is 5 (μm), and the channel length L is 20 (μm), and, in the switching transistors 40A, the channel width W is 5 (μm), and the channel length L is 5 (μm). Namely, the parameters of the driving transistors 20B relating to the channel size (W/L) are identical in the light-emitting cells of all of R, G, and B. Therefore, a difference is not produced among the aperture ratios of the R-color light-emitting cells, the G-color light-emitting cells, and the B-color light-emitting cells.

Actually, the gate insulating film thickness d cannot be changed by a very large degree, and hence the aperture ratio cannot be sufficiently improved only by adjusting the gate insulating film thickness d. In the case where a practical device is to be configured, therefore, the driving transistors 20A which are different from each other in mobility μ are formed in a similar manner to FIG. 1A, and then a condition of (the gate insulating film thickness d of the driving transistor 20A of the R-color light-emitting cell)<(the gate insulating film thickness d of the driving transistor 20A of the G-color light-emitting cell)<(the gate insulating film thickness d of the driving transistor 20A of the B-color light-emitting cell) is set. According to the configuration, as compared with the case where only the mobilities μ are adjusted, the channel length L of the driving transistor 20A can be further shortened, and therefore the aperture ratio can be further improved.

By contrast, in the configuration example shown in FIG. 1C, in a similar manner to the case of FIG. 2, the organic EL element 10, a driving transistor 20C, the capacitor 30, and the switching transistor 40A are formed in one light-emitting cell. However, the gate insulating films of the driving transistors 20C are formed by using materials in which the dielectric constants ε are different depending on the light-emitting cells of R, G, and B.

As shown in FIG. 1C, namely, the driving transistors 20B disposed in the light-emitting cells of R, G, and B are formed so that the dielectric constants (ε3R, ε2G, ε1B) of their gate insulating films are “15”, “10”, and “5”, respectively. Specifically, “SiN” is employed as the material of the gate insulating films of the driving transistors 20C in the R-color light-emitting cells, “SiON” is employed as the material of the gate insulating films of the driving transistors 20C in the G-color light-emitting cells, and “SiO₂” is employed as the material of the gate insulating films of the driving transistors 20C in the B-color light-emitting cells. As a result, the dielectric constants of the gate insulating films of the drive transistors 20C in the light-emitting cells of R, G, and B have a relationship of (ε3R >ε2G >ε1B).

Actually, since materials which can be used as a gate insulating film are restricted, it is difficult to largely change the gate insulating film dielectric constant ε, and hence the aperture ratio cannot be sufficiently improved only by adjusting the gate insulating film dielectric constant ε. In the case where a practical device is to be configured, therefore, the driving transistors 20A which are different from each other in mobility μ are formed in a similar manner to FIG. 1A, and then a condition of (the dielectric constant ε of the gate insulating film of the driving transistor 20A of the R-color light-emitting cell)>(the dielectric constant ε of the gate insulating film of the driving transistor 20A of the G-color light-emitting cell)>(the dielectric constant ε of the gate insulating film of the driving transistor 20A of the B-color light-emitting cell) is set. According to the configuration, as compared with the case where only the mobilities μ are adjusted, the channel length L of the driving transistor 20A can be further shortened, and therefore the aperture ratio can be further improved.

Furthermore, it may be contemplated that the adjustment of the mobilities μ such as shown in FIG. 1A, that of the gate insulating film thicknesses (d) such as shown in FIG. 1B, and that of the gate insulating film dielectric constants (ε) such as shown in FIG. 1C are combined with one another to form the driving transistor 20 having necessary characteristics, for each of the light-emitting cells of R, G, and B.

Next, specific examples of a production process which can be used for producing plural elements that are different from one another in electron carrier concentration, as the above-described driving transistors 20 on a common substrate will be described.

### SPECIFIC EXAMPLE 1 OF PRODUCTION PROCESS

As shown in FIG. 6, an insulating film is formed on a substrate 60, and thereafter gate electrodes 61, 62 constituting the transistors are formed thereon by film formation and patterning of an electrode material. Then, gate insulating films 63, 64 are formed thereon by film formation and patterning of an insulating material. Next, two active layers 65, 66 are formed thereon. The formation of the active layers 65, 66 is processed in the following manner.

While using a polycrystalline sintered body having a composition of InGaZnO₄ as a target, the process is performed by the RF magnetron sputtering vacuum deposition method. In this example, the following conditions are employed:
Flow rate of argon (Ar): 12 sccm,
Flow rate of oxygen (O₂): 1.4 sccm,
RF power: 200 W, and
Pressure: 0.4 Pa.

As a result of the process, the active layer 65 has the following characteristics (the same is true in the active layer 66):
Electrical conductivity: 5.7×10⁻³ Scm⁻¹,
Electron carrier concentration: 1×10¹⁶ cm⁻³, and
Hall mobility: 3.0 cm²/V·S.

As shown in FIG. 6, next, a UV mask 67 having an opening 67a in a place opposing to the active layer 66 is placed to cover the surface of the active layer 65, and only the active layer 66 is irradiated with UV light (11.6 mW) for one minute by using a UV light source 68.

As a result of the process, the active layer 66 has the following characteristics:
Electrical conductivity: 4.0×10¹ Scm⁻¹,
Electron carrier concentration: 3×10¹⁹ cm⁻³, and
Hall mobility: 8.3 cm²/V·S.

Between the transistor which is configured by using the thus formed active layer 65, and that which is configured by using the active layer 66, a difference in electron carrier concentration is produced, and also that in mobility μ is produced. It is found that, when the UV irradiation amount is increased, also the electron carrier concentration is increased correspondingly with the irradiation amount. Therefore, the electron carrier concentration can be adjusted by adjusting the UV irradiation amount.

### SPECIFIC EXAMPLE 2 OF PRODUCTION PROCESS

As shown in FIG. 7, an insulating film is formed on a substrate 70, and thereafter gate electrodes 71, 72 constituting the transistors are formed thereon by film formation and patterning of an electrode material. Then, gate insulating films 73, 74 are formed thereon by film formation and patterning of an insulating material. Next, two active layers 75, 76 are formed thereon. The formation of the active layers 75, 76 is processed in the following manner.

While using a polycrystalline sintered body having a composition of InGaZnO₄ as a target, the process is performed by the RF magnetron sputtering vacuum deposition method. In this example, the following conditions are employed:
Flow rate of argon (Ar): 12 sccm,
Flow rate of oxygen (O2): 1.4 sccm,
RF power: 200 W, and
Pressure: 0.4 Pa.

As a result of the process, the active layer 75 has the following characteristics (the same is true in the active layer 76):
Electrical conductivity: 5.7×10⁻³ Scm⁻¹,
Electron carrier concentration: 1×10¹⁶ cm⁻³, and
Hall mobility: 3.0 cm²/V·S.

As shown in FIG. 7, next, a mask 77 having an opening 77a in a place opposing to the active layer 76 is placed to cover the surface of the active layer 75, and only the active layer 76 is irradiated with Ar plasma (150 W, 0.1 Torr) for 30 seconds by using an Ar plasma apparatus 78.

As a result of the process, the active layer 76 has the following characteristics:
Electrical conductivity: 1.0×10² Scm⁻¹,
Electron carrier concentration: 8×10¹⁹ cm⁻³, and
Hall mobility: 19.2 cm²/V·S.

Between the transistor which is configured by using the thus formed active layer 75, and that which is configured by using the active layer 76, a difference in electron carrier concentration is produced, and also that in mobility μ is produced. It is found that, when the plasma irradiation time is extended (the irradiation amount is increased), also the electron carrier concentration is increased correspondingly with the irradiation time. Therefore, the electron carrier concentration can be adjusted by adjusting the plasma irradiation amount.

In the case where an organic electroluminescent display device is configured by using light-emitting cells of R, G, and B, it is necessary to form the driving transistors 20 which have different characteristics of the mobility μ depending on the light-emitting cells of R, G, and B. Also in this case, as described above, the active layers are irradiated with UV rays or Ar plasma, whereby three kinds of driving transistors 20A having different electron carrier concentrations or mobilities can be produced on a common substrate.

In the Ar plasma irradiation process such as shown in FIG. 7, many light-emitting cells can be collectively processed. Therefore, the characteristics of the cells are less dispersed, and display unevenness is reduced. In the case where polysilicon is used, such a batch process is hardly performed. When an IGZO or IZO amorphous oxide semiconductor is used as the active layers, however, such a batch process is enabled.

In the examples shown in FIGS. 6 and 7, the case where the amorphous oxide TFTs are configured by using a material having a composition of InGaZnO₄ (IGZO) is assumed. Alternatively, the amorphous oxide TFTs may be configured by using a material having an IZO composition.

FIGS. 8 and 9 show examples of a process procedure of a production process of producing three kinds of transistors having different mobility characteristics on one substrate.

First, the process procedure shown in FIG. 8 will be described.

In step S11, plural independent active layers are formed on one substrate in a manner similar to the example shown in FIG. 6. Although the two active layers (65, 66) are formed in the example shown in FIG. 6, the case where the driving transistors 20A having three kinds characteristics are formed is assumed in the process procedure shown in FIG. 8. In step S11, therefore, three active layers of “R-color active layer”, “G-color active layer”, and “B-color active layer” are formed on the substrate.

In step S12, among the three active layers, only “R-color active layer” and “B-color active layer” are covered by a mask.

In step S13, “G-color active layer” which is exposed to the surface is irradiated with UV rays or plasma in a manner similar to the example shown in FIG. 6 or 7. The irradiation amount in this process is X1.

In step S14, the mask of step S12 is removed, and thereafter only “G-color active layer” and “B-color active layer” of the three active layers are covered by a mask.

In step S15, “R-color active layer” which is exposed to the surface is irradiated with UV rays or plasma in a manner similar to the example shown in FIG. 6 or 7. The irradiation amount in this process is X2. The irradiation amounts are set so that the relationship of “X1<X2” is satisfied.

As a result of the above-described process, among the three active layers, “B-color active layer” is not irradiated with UV rays or plasma, “R-color active layer” and “G-color active layer” are irradiated with UV rays or plasma, and the amount of the irradiation on “G-color active layer” is smaller than that on “R-color active layer”. Therefore, a relationship of (“mobility of R-color active layer”>“mobility of G-color active layer”>“mobility of B-color active layer”) is satisfied, and also a relationship of (“electron carrier concentration of R-color active layer”>“electron carrier concentration of G-color active layer”>“electron carrier concentration of B-color active layer”) is satisfied.

In step S16, therefore, the driving transistor 20A for the R-color light-emitting cell is formed by using “R-color active layer”, the driving transistor 20A for the G-color light-emitting cell is formed by using “G-color active layer”, and the driving transistor 20A for the B-color light-emitting cell is formed by using “B-color active layer”. As a result, characteristics which are required in the driving transistors 20A for the light-emitting cells of R, G, and B having the configuration shown in, for example, FIG. 1A can be differentiatedly produced.

Next, the process procedure shown in FIG. 9 will be described.

In step S21, plural independent active layers are formed on one substrate in a manner similar to the example shown in FIG. 6. Although the two active layers (65, 66) are formed in the example shown in FIG. 6, the case where the driving transistors 20A having three kinds characteristics are formed is assumed in the process procedure shown in FIG. 9. In step S21, therefore, three active layers of “R-color active layer”, “G-color active layer”, and “B-color active layer” are formed on the substrate.

In step S22, among the three active layers, only “R-color active layer” and “G-color active layer” are covered by a mask.

In step S23, “B-color active layer” which is exposed to the surface is irradiated with UV rays or plasma in a manner similar to the example shown in FIG. 6 or 7. The irradiation amount in this process is X1.

In step S24, the mask of step S22 is removed, and thereafter only “R-color active layer” and “B-color active layer” of the three active layers are covered by a mask.

In step S25, “G-color active layer” which is exposed to the surface is irradiated with UV rays or plasma in a manner similar to the example shown in FIG. 6 or 7. The irradiation amount in this process is X2. The irradiation amounts are set so that a relationship of “X1<X2” is satisfied.

In step S26, the mask of step S24 is removed, and thereafter only “G-color active layer” and “B-color active layer” of the three active layers are covered by a mask.

In step S27, “R-color active layer” which is exposed to the surface is irradiated with UV rays or plasma in a manner similar to the example shown in FIG. 6 or 7. The irradiation amount in this process is X3. The irradiation amounts are set so that a relationship of “X1<X2<X3” is satisfied.

As a result of the above-described process, the three active layers are irradiated with UV rays or plasma, and the irradiation amounts satisfy the relationship of “X1<X2<X3”. Therefore, the relationship of (“mobility of R-color active layer”>“mobility of G-color active layer”>“mobility of B-color active layer”) is satisfied, and also the relationship of (“electron carrier concentration of R-color active layer”>“electron carrier concentration of G-color active layer”>“electron carrier concentration of B-color active layer”) is satisfied.

In step S28, therefore, the driving transistor 20A for the R-color light-emitting cell is formed by using “R-color active layer”, the driving transistor 20A for the G-color light-emitting cell is formed by using “G-color active layer”, and the driving transistor 20A for the B-color light-emitting cell is formed by using “B-color active layer”. As a result, characteristics which are required in the driving transistors 20A for the light-emitting cells of R, G, and B having the configuration shown in, for example, FIG. 1A can be differentiatedly produced.

In the case where the driving transistors 20 are to be configured by using an amorphous oxide semiconductor, the characteristics of the driving transistors 20A in the light-emitting cells of the colors can be differentiatedly produced by the steps such as shown in FIG. 8 or 9, so that the production is facilitated and the production cost can be reduced. Moreover, it is requested only to repeat two or three times the step of UV or plasma irradiation, and many light-emitting cells can be collectively processed. Therefore, characteristic dispersions of the cells can be reduced, and display unevenness can be suppressed.

In the case where the characteristics of the driving transistors 20A in the light-emitting cells of R, G, and B are differentiated depending on the difference in mobility, it is not required to increase the channel sizes (L) of the transistors, and hence there is no difference in aperture ratio among the colors. As a result, a bright high-quality display is enabled at low power consumption.

When the current of the driving transistor 20A is restricted depending on a difference in mobility (μ), gate insulating film thickness (d), or dielectric constant (ε), it is not required to lower the program voltage (Vp). Therefore, the noise level can be suppressed, and a high-quality display is enabled.

As described above, according to the organic electroluminescent display device of the embodiment, when the driving transistors 20 disposed in the light-emitting cells of R, G, and B are driven under same conditions, the output current amounts satisfy the relationship of (the output current amount of the driving transistor 20 disposed in the R-color light-emitting cell)<(the output current amount of the driving transistor 20 disposed in the G-color light-emitting cell)<(the output current amount of the driving transistor 20 disposed in the B-color light-emitting cell). Therefore, an adequate white balance can be ensured, and it is not required to control the power source voltage depending on the emission color of the organic EL element 10.

According to the organic electroluminescent display device of the embodiment, moreover, an adequate output current amount is realized depending on the difference in mobility of the driving transistors 20. Therefore, it is not necessary to increase the channel lengths of the driving transistors 20, and the aperture ratio can be prevented from being reduced. Furthermore, the difference in mobility can be obtained from the difference in electron carrier concentration of the active layers. Therefore, the production process is facilitated, and dispersion of the characteristics of the light-emitting cells can be reduced by the batch process. In the case where the active layer of the driving transistor 20 is formed by using an amorphous oxide semiconductor, particularly, the output current amount can be easily restricted as compared with the case where polysilicon is used, because an amorphous oxide semiconductor has a relatively small mobility of about 10.

In the above description, the organic electroluminescent display device has the light-emitting cells of the three RGB colors. Even in a configuration where the organic electroluminescent display device has light-emitting cells of four or more colors, the aperture ratios of the light-emitting cells can be prevented from being reduced, by adjusting the output current amounts of driving transistors in the light-emitting cells of the colors in the above-described method.

Although the invention has been described above in relation to preferred embodiments and modifications thereof, it will be understood by those skilled in the art that other variations and modifications can be effected in these preferred embodiments without departing from the scope and spirit of the invention.

What is claimed is:

1. An organic electroluminescent display device in which a plurality of light-emitting cells each having an organic electroluminescent portion are arranged on a substrate, wherein
a plurality of organic electroluminescent portions included in said plurality of light-emitting cells comprise at least three organic electroluminescent portions which emit different colors,
each of said light-emitting cells has a driving transistor which drives said organic electroluminescent portion included in said light-emitting cell, and
an amount of an output current of said driving transistor under same driving conditions is different depending on emission color of said organic electroluminescent portion included in said light-emitting cell comprising said driving transistor.

2. The organic electroluminescent display device according to claim 1, wherein a difference in amount of the output currents of said driving transistors is obtained from a difference in mobility of said driving transistors.

3. The organic electroluminescent display device according to claim 2, wherein
said plurality of organic electroluminescent portions included in said plurality of light-emitting cells comprise R-color organic electroluminescent portions which emit red light, G-color organic electroluminescent portions which emit green light, and B-color organic electroluminescent portions which emit blue light, and,
in said driving transistors, an R-color mobility indicating mobilities of R-color driving transistors which drive said R-color organic electroluminescent portions, a G-color mobility indicating mobilities of G-color driving transistors which drive said G-color organic electroluminescent portions, and B-color mobility indicating mobilities of B-color driving transistors which drive said B-color organic electroluminescent portions have a relationship of
(R-color mobility)>(G-color mobility)>(B-color mobility).

4. The organic electroluminescent display device according to claim 2, wherein a difference in mobility of said driving transistors is obtained from a difference in electron carrier concentration of active layers of said driving transistors.

5. The organic electroluminescent display device according to claim 3, wherein a difference in mobility of said driving transistors is obtained from a difference in electron carrier concentration of active layers of said driving transistors.

6. The organic electroluminescent display device according to claim 1, wherein a difference in amount of the output currents of said driving transistors is obtained from a difference in thickness of gate insulating films of said driving transistors.

7. The organic electroluminescent display device according to claim 2, wherein a difference in amount of the output currents of said driving transistors is obtained from a difference in thickness of gate insulating films of said driving transistors.

8. The organic electroluminescent display device according to claim 3, wherein a difference in amount of the output currents of said driving transistors is obtained from a difference in thickness of gate insulating films of said driving transistors.

9. The organic electroluminescent display device according to claim 6, wherein
said plurality of organic electroluminescent portions included in said plurality of light-emitting cells comprise R-color organic electroluminescent portions which emit red light, G-color organic electroluminescent portions which emit green light, and B-color organic electroluminescent portions which emit blue light, and,
in said driving transistors, an R-color gate insulating film thickness indicating thicknesses of gate insulating films of R-color driving transistors which drive said R-color organic electroluminescent portions, a G-color gate insulating film thickness indicating thicknesses of gate insulating films of G-color driving transistors which drive said G-color organic electroluminescent portions, and a B-color gate insulating film thickness indicating thicknesses of gate insulating films of B-color driving transistors which drive said B-color organic electroluminescent portions have a relationship of
(R-color gate insulating film thickness)<(G-color gate insulating film thickness)<(B-color gate insulating film thickness).

10. The organic electroluminescent display device according to claim 7, wherein
said plurality of organic electroluminescent portions included in said plurality of light-emitting cells comprise R-color organic electroluminescent portions which emit red light, G-color organic electroluminescent portions which emit green light, and B-color organic electroluminescent portions which emit blue light, and,
in said driving transistors, an R-color gate insulating film thickness indicating thicknesses of gate insulating films of R-color driving transistors which drive said R-color organic electroluminescent portions, a G-color gate insulating film thickness indicating thicknesses of gate insulating films of G-color driving transistors which drive said G-color organic electroluminescent portions, and a B-color gate insulating film thickness indicating thicknesses of gate insulating films of B-color driving transistors which drive said B-color organic electroluminescent portions have a relationship of
(R-color gate insulating film thickness)<(G-color gate insulating film thickness)<(B-color gate insulating film thickness).

11. The organic electroluminescent display device according to claim 8, wherein
said plurality of organic electroluminescent portions included in said plurality of light-emitting cells comprise R-color organic electroluminescent portions which emit red light, G-color organic electroluminescent portions which emit green light, and B-color organic electroluminescent portions which emit blue light, and,
in said driving transistors, an R-color gate insulating film thickness indicating thicknesses of gate insulating films of R-color driving transistors which drive said R-color organic electroluminescent portions, a G-color gate insulating film thickness indicating thicknesses of gate insulating films of G-color driving transistors which drive said G-color organic electroluminescent portions, and a B-color gate insulating film thickness indicating thicknesses of gate insulating films of B-color driving transistors which drive said B-color organic electroluminescent portions have a relationship of
(R-color gate insulating film thickness)<(G-color gate insulating film thickness)<(B-color gate insulating film thickness).

12. The organic electroluminescent display device according to claim 1, wherein a difference in amount of the output currents of said driving transistors is obtained from a difference in dielectric constant of gate insulating films of said driving transistors.

13. The organic electroluminescent display device according to claim 12, wherein
said plurality of organic electroluminescent portions included in said plurality of light-emitting cells comprise R-color organic electroluminescent portions which emit red light, G-color organic electroluminescent portions which emit green light, and B-color organic electroluminescent portions which emit blue light, and,
in said driving transistors, an R-color insulating film dielectric constant indicating dielectric constants of gate insulating films of R-color driving transistors which drive said R-color organic electroluminescent portions, a G-color insulating film dielectric constant indicating dielectric constants of gate insulating films of G-color driving transistors which drive said G-color organic electroluminescent portions, and a B-color insulating film dielectric constant indicating dielectric constants of gate insulating films of B-color driving transistors which drive said B-color organic electroluminescent portions have a relationship of
(R-color insulating film dielectric constant)>(G-color insulating film dielectric constant)>(B-color insulating film dielectric constant).

14. The organic electroluminescent display device according to claim 1, wherein active layers of said driving transistors are formed by an amorphous oxide semiconductor.

15. The organic electroluminescent display device according to claim 2, wherein active layers of said driving transistors are formed by an amorphous oxide semiconductor.

16. The organic electroluminescent display device according to claim 3, wherein active layers of said driving transistors are formed by an amorphous oxide semiconductor.

17. The organic electroluminescent display device according to claim 4, wherein active layers of said driving transistors are formed by an amorphous oxide semiconductor.

18. The organic electroluminescent display device according to claim 5, wherein active layers of said driving transistors are formed by an amorphous oxide semiconductor.

19. The organic electroluminescent display device according to claim 6, wherein active layers of said driving transistors are formed by an amorphous oxide semiconductor.

20. A method for producing an organic electroluminescent display device in which a plurality of light-emitting cells each having an organic electroluminescent portion are arranged on a substrate, wherein
a plurality of organic electroluminescent portions included in said plurality of light-emitting cells comprise at least three kinds of organic electroluminescent portions which emit different colors,
each of said light-emitting cells has a driving transistor which drives said organic electroluminescent portion included in said light-emitting cell,
said method comprises:
a first step of forming active layers of said driving transistors on said substrate; and
a second step of irradiating said active layers of said driving transistors which drive at least two kinds of organic electroluminescent portions among said at least three kinds of organic electroluminescent portions, respectively, with ultraviolet ray or plasma, and,
in said second step, an amount of irradiation of the ultraviolet ray or plasma on said active layers is different depending on the kinds of said organic electroluminescent portions which are driven by said driving transistors including said active layers.
